(19) United States
(12) Patent Application Publication
(10) Pub. No.: US 2006/0199309 A1
(43) Pub. Date: Sep. 7, 2006

(54) High thermal conductive compounds

(76) Inventor: Jared L. Sommer, North Salt Lake, UT (US)

Correspondence Address: HOLME ROBERTS & OWEN, LLP, 299 SOUTH MAIN, SUITE 1800, SALT LAKE CITY, UT, 84111, US

(21) Appl. No.: 11/362,412

(22) Filed: Feb. 23, 2006

Related U.S. Application Data
(60) Provisional application No. 60/656,163, filed on Feb. 25, 2005.

(51) Int. Cl. H01L 21/00; B01J 3/06; H01L 23/34

(52) U.S. Cl. 438/122; 257/712; 423/446

(57) ABSTRACT

A multimodal particles having aspect ratios from 1 to about 1.6, for example multimodal diamond powder, is mixed into a suitable base like epoxy, potting compound or adhesive to form a compound with enhanced thermal conductivity. The powder may be hydrogenated in a blanket of hydrogen in an furnace after the furnace is purged by nitrogen or an inert gas to improve the aspect ratio.

### CROSS-REFERENCE TO RELATED APPLICATIONS

This application claims the benefit of U.S. Provisional Application No. 60/656,163, filed Feb. 25, 2005, which is incorporated herein by reference.

### BACKGROUND OF THE INVENTION

1. The Field of the Invention

This invention relates to compounds or composites, which are formed from a base material, which has a low thermal conductivity, and from a thermally conductive material in powder form, intermixed therein when the base material is in a liquid form.

2. The Relevant Technology

Removing heat from electrical and electronic products is typically of concern because heat may damage the electrical and electronic components. Similarly, a wide variety of other products, including, but not limited to, brakes, transmissions, electrical motors, sealed pumps, and other devices having moving parts generate heat by friction or otherwise, which one desires to remove. In some cases, housings or casings are made of metals (with high thermal conductivity) to facilitate heat transfer out of or away from the device or component. In others, arrangements are made for convection cooling. In other cases, systems are used to remove undesired or excess heat by forcing air or other coolants through the device.

While metal housings or casings have been used to transfer heat away from a device, such casings or housings have typically not been suitable. While metals typically have a high thermal coefficient, they may also be highly electrically conductive and/or induce/enhance or magnify EMI (electromagnetic interference). For example, many metals are thermally conductive and also electrically conductive. At the same time, many metals may enhance or exasperate EMI. To avoid EMI and also for mechanical stability, many electronic components are encased in an epoxy or other similar material. While some materials are said to be thermally conductive, for example compound SE 4410 offered by Dow Corning, the thermal conductivity is still marginal. In turn, compounds or composites that are both highly heat conductive and highly electrically insulating are desired.

Electrical components are typically encased in a housing or casing that is electrically non-conductive or essentially non-conductive. Such materials also do not enhance, and in fact, may reduce EMI problems for internal circuits. Because heat transfer through such housings or casings is limited, heat transfer from the interior of a product can be enhanced or facilitated by forming its housing or casing from a compound, such as an epoxy molding compound (EMC) using a base in a liquid form and adding materials with a higher thermal conductivity (e.g. 55-75% by volume). An EMC known as SE 4410 offered by Dow Corning is believed to include alumina to increase thermal conductivity. Such combinations or compounds are then cured to form the casing or housing. The additive material such as alumina is said to be in powder or granular form which is generally believed to be material made up of small particles of under about 125 microns at the largest axis, with some powders having particles as small as 15 microns for the largest dimension. The thermal conductivity is nonetheless believed to be relatively low and less than about 1 to 4 W/mK. (Watts per meter Kelvin)

The casings or housings from epoxy resins typically have suitably high electrical resistance but at the same time have a thermal conductivity low enough that heat cannot be dissipated adequately, which can lead to thermal expansion mismatch between the housing or casing and the components within the housing or casing. In turn, mechanical damage can occur as a result of poor heat dissipation and thermal expansion mismatch.

Adding a fused silicon dioxide (SiO2) filler slightly increases the thermal conductivity while notably reducing the thermal expansion coefficient. Alternate fillers have been considered, including alumina (as mentioned), AlN (aluminum nitride), BN (boron nitride), diamond and SiC (silicon carbide) materials. All are added to the epoxy molding compound to enhance the transfer of heat, to increase the thermal conductivity (K) and to substantially reduce the coefficient of thermal expansion coefficient to an acceptable range. The following Table 1 lists thermal conductivities (Kf) of selected materials along with their respective coefficients of thermal expansion.

TABLE 1

| | | CTE (Coefficient of |
|---|---|---|
| | | Thermal Expansion) |
| | Thermal Conductivity | PPM/C. (parts per |
| Filler Material | (K_{f} W/mk | million per degree C.) |
| Epoxy | 0.25-0.40 | 60-180 |
| Fused SiO₂ | 1.5 | 0.5 |
| AlN | 180 | ≈4 |
| BN | 29 | 4.3 |
| Natural Diamond | 2000 | 1.2 |
| Synthetic Diamond | 700-1400 | ≈1.2 |
| SiC | 85 | 4.7 |

The ratio (K_{f}/Kᵣ) of the thermal conductivity of the filler (K_{f}) to the thermal conductivity of the epoxy molding compound or resin (Kᵣ) can be substantially enhanced by selecting filler materials with higher thermal conductivities. While the ratio can be less than 10 using silicon dioxide compounds, it can exceed 1000 when the filler material is a powder of diamonds. Most commercial diamond powders, for example, are made up of individual grains or particles having an aspect ratio from about 1.3 to 1.6. They are not uniform in shape or size and are sometimes described as blocky. Also, such powders tend to be highly abrasive when mixed into an EMC leading to high mold wear.

A diamond filler up to 50% by volume was examined as an alternate to silicone dioxide because diamond has a high heat transfer coefficient. P. Procter and J. Sole, “Improved Thermal Conductivity in Microelectronic Encapsulants,” Dexter Technical Paper, February 1999. Nevertheless, the cured resins containing 50% by volume of diamond powder exhibited approximately the same thermal conductivity as a composite with 50% BN (Boron Nitride) or SiC (Silicon Carbide) powder as the filler.

The size of the fused silica powder has been selected to obtain a high packing density in the epoxy liquid before the housing or casing is formed to enhance the thermal conductivity. Indeed, it is recognized that relative thermal conductivity of composite molding materials increases as the filler volume increases. L. E. Nielsen, “Thermal Conductivity of Particulate-Filled Polymers,” J. Appl. Polym. Sci., 17, p. 3819 (1973).

Nevertheless, filler volume densities have been limited by the nature of the filler selected. Means and methods to enhance filler volume densities or to otherwise provide for enhanced thermal conductivity while providing suitable control of the thermal expansion of the housing or casing and at the same time continuing to provide desired electrical insulation.

Similarly, adhesive compounds used to mount or attach such products to a suitable substrate for use typically have a poor or low thermal conductivity. Thus, various high conductivity fillers have been mixed into the adhesive to increase the thermal conductivity and in turn, facilitate the transfer of heat away from the casing or housing to the atmosphere or to a suitable heat sink. These materials include AlN, BN, diamond and silicon carbide have been used in lieu of silica to enhance thermal conductivity. Despite some enhancement, the thermal conductivity of the different compounds within the polymer matrix are similar.

### SUMMARY OF THE INVENTION

A method for forming a compound for use in connection with heat generating products to facilitate the transmission of heat from the heat generating products. The method involves the mixing together of a curable material with powder-like material having a selected thermal conductivity greater than the thermal conductivity of the curable material. The material in preferred methods is formed of multimodal particles having aspect ratios from 1 to about 1.6, more preferably from 1 to about 1.4.

In alternate preferred methods, the powder-like material is hydrogenated on the surface by supplying a furnace and a source of hydrogen and heating the powder-like material in the hydrogen environment to chemically bond hydrogen atoms on the surface of the powder. In use the compound is then positioned proximate a heat source to facilitate the transfer of heat therefrom. The powder-like material can be any material with a thermal conductivity that is higher than the base or curable material that it can be put into or that appears in the form of a powder formed from particles which all have aspect ratios from 1 to about 1.6, more preferably about 1.4. In other words, the powder is made of many particles, some of which particles have an aspect ratio of 1 and others have different aspect ratios that vary higher.

An aspect ratio is the ratio of maximum dimension (e.g., height, width, length, diameter) divided by the minimum dimension. A sphere would have an aspect ratio of 1. A long needle shaped object could have a very large aspect ratio.(e.g., well above three).

Preferably the powder-like material is diamond powder. In one configuration the curable material is an adhesive for securing the heat generating products to a substrate like a circuit board or to a heat sink.

In an alternate and equally preferred embodiment, a mold is provided for forming the casing of an electronic product. The compound is placed or injected into the mold and cured to form a casing or housing for electronic product. The casing or housing is more heat conductive than the curable material by itself which can be an epoxy.

In a highly preferred and alternate method, the powder like material is first positioned into a high temperature furnace. The furnace is then purged with an inert gas. Thereafter hydrogen sufficient to hydrogenate said powder-like material is introduced and flowed into the furnace. The furnace is then heated with the hydrogen and said powder-like material to a temperature sufficient to hydrogenate said powder-like material. Preferably the powder-like material is multimodal diamond particles and most preferably multimodal diamond particles have an aspect ratio from 1 to about 1.6 or about 1.4. An optional agitator may be attached to the furnace to mix or stir the powder. Alternately, the container with the powder can be rotated.

In one embodiment the curable material is epoxy. In an alternate arrangement, the curable material is an adhesive from the group of adhesives that include bismaleimide.

In one more preferred procedure, the adhesive is bismaleimide.

In preferred procedures, a least about 50% and less than about 90% of the volume of said compound is said powder-like material. More preferably, at least about 75% and less than about 90% of the volume of said compound is the powder-like material.

In specific alternate processes, a compound for use with electronic components is formed using a curable material which is an electrical insulator when cured. A powder-like material is mixed into the curable material to form a compound. The powder-like material has a selected thermal conductivity greater than the thermal conductivity of the curable material and is preferably formed of multimodal particles having aspect ratios, for example, from 1 to about 1.4. Of course the mixture or compound may be placed in a suitable mold for forming the casing or housing of an electronic component and then cured.

In preferred practice, the curable material is an epoxy and the powder-like material is diamond powder. Preferably the powder-like material is at least about 50 per cent by volume and most preferably at least 75 per cent and less than about 90 percent by volume of the compound.

Alternate configurations of said compound involve diamond powder which has a selected thermal conductivity greater than the thermal conductivity of an adhesive such as bismaleimide. The diamond powder is formed of multimodal particles having aspect ratios, for example, from 1 to about 1.4. The adhesive is used to secure the heat-generating product to a substrate or to a heat sink.

These and other objects and features of the present invention will become more fully apparent from the following description and appended claims, or may be learned by the practice of the invention as set forth hereinafter.

### DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 depicts a heat-generating source proximate a substrate and a heat sink;

FIG. 2 is a depiction of a composite formed of a base with a filler material having particles of selected different sizes;

FIG. 3 is a depiction of a composite formed of a base with a filler material having particles of selected random sizes having edges and points;

FIG. 4 is a depiction of a composite formed of a base with a filler material having particles of selected different sizes; and

FIG. 5 depicts a process for treating filler material of different sizes to enhance thermal conductivity.

### DETAILED DESCRIPTION OF THE PREFERRED EMBODIMENTS

A wide variety of mechanical and electronic components or products produce heat when in use. Mechanical devices such as gears, transmissions, and the like as well as a wide range of electrical and electronic components like chips, wafers, integrated circuits, transformers, power supplies, application specific integrated circuits (ASIC's), and the like all produce heat in the normal course of operation. They all come in a wide range of configurations. That is, the size and shape vary widely.

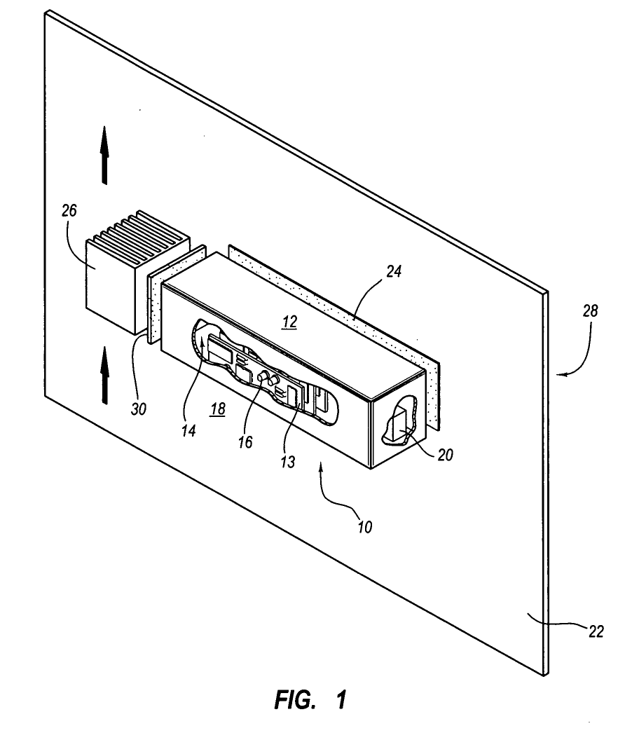

FIG. 1 depicts a theoretical electronic heat-generating source 10 which is in this illustration a theoretical electronic component. It represents many different forms or types of products. The illustration is simply to facilitate discussion. The product 10 has a casing or housing 12 shown with some cut-a-way portion to illustrate any one of many different kinds of interior circuits 13 in the interior 14. The circuit 13 contains multiple electronic heat-generating components 16. In operation, the components 16 generate heat which is to be removed from the interior 14 by causing the heat to transfer through the casing or housing 12 to exterior 18 the casing or housing 12. In some cases, the components 16 are held in place by a potting compound 20; and the heat must pass through the compound 20 to reach the casing or housing 12.

The heat-generating source 10 is here depicted attached to a circuit board 22 by an adhesive 24. A heat sink 26 may also be mounted to the board 22 on the side 28 opposite to the heat-generating product 10 or to the heat-generating source 10 itself by an adhesive 30.

The casing or housing 12 of the heat-generating source 10 is here made of a curable material which is, in this embodiment, any suitable encapsulating material that is in liquid form and then cured into solid form. When in liquid form, a suitable powder is added to it to create a compound or composite that can be cured to a solid form with enhanced thermal transmission characteristics.

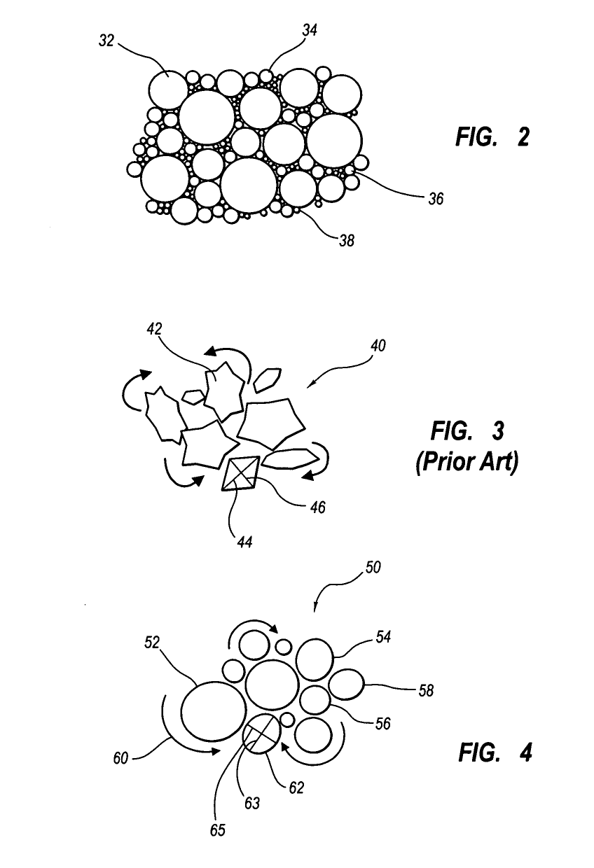

In FIG. 2, a cured compound is shown in a highly enlarged and theoretical arrangement to include a suitable powder of a material that has a high thermal conductivity. While a diamond powder is here preferred, other thermally conductive materials may be selected. The powder is multimodal and may be comprised of large particles intermixed with particles smaller in size. Powders typically have particles which are in a continuum in size from large to small. For example it may be comprised of a plurality of large particles 32 intermixed with larger pluralities of medium particles 34 and larger plurality of small particles 36. In practice there may be particles of many different sizes typically found in powders made up of nonhomogenous particles. The particles 32, 34 and 36 are here depicted to be spherical in shape while in practice some particles may be non spherical and have a major and minor axis while others may have edges or points. It is believed that using a powder that has particles of many different sizes with many of a shape essentially spherical, when intermixed into an epoxy resin, adhesive or potting compound in liquid state, will permit higher volume fractions of such powder to mix therein and create many more points of contact between the particles 32, 34 and 36. It is believed that the thermal conductivity of the compound increases with the increase in the points of contact between the particles of the powder mixed into the epoxy in a liquid state. Thus a powder that is multi-modal is preferred. That is, the powder is comprised of particles of many different sizes which particles are all shaped to allow increased volume fractions (percentage by volume of the total composite or compound) of powder when intermixed with a base such as an epoxy. While the preferred shape may be spherical, other shapes in which particles have major and minor axis and even some edges and points may be included. Selection of the powder and epoxy volume fractions also impacts on viscosity and in turn the ability to practically work with the compound before it is cured.

In FIG. 2, the powder is shown as a plurality of large to small circles with the base (e.g., epoxy) interspersed outside of the circles to form an effective compound and composite. Depending on the epoxy or other base selected, the material may be cured into the casing or housing for integrated circuits 13. It may also cure into the potting material like compound 20 useful inside the casing or housing 12. It may also be an adhesive like adhesives 24 and 30 which are used to attach a product to a circuit board or proximate a heat sink like heat sink 26. While epoxy is mentioned, it should be understood that a wide range of thermoplastic and thermoset materials may be equally suitable based on the particulars of a given application.

Powder 40 of the prior art is depicted in FIG. 3 to show what it is believed to look like when enlarged. The particles 42 particularly of diamond are of random geometrical shape with edges and points all that randomly abut each other and which in turn inhibit dense packing and in turn reduce the ability of the compound with the powder to transmit heat. The separate particles all have an aspect ratio which is length of the longest axis 44 divided by the length of the shortest axis 46.

In FIG. 4, an epoxy compound includes powder 50 that is formed of particles 52, 54, 56 and 58. The particles 52, 54, 56 and 58 are preferably mostly spherical or substantially so and, in turn, do not have any notable edges, points, ledges and ridges to catch or lock to inhibit movement and rotation. While some particles of the powder are believed to have edges, points, ledges and ridges, the powder is made up mostly of particles that have smooth edges. Smooth edges can be obtained by sifting or by mechanically treating the powder by grinding or some other process to smooth edges and remove points. The powder 50 is made up of particles with aspect ratios that extend from 1.0 to about 1.4 and even as high as 1.6. It is believed that the round or smooth edges as depicted in FIG. 4 facilitate rotation 60 in the epoxy mixture before it is cured so that the epoxy before cure (in the liquid state) exhibits a lower viscosity. While mixing is thereby facilitated, so also is the transfer and application of the compound after mixing before it is cured.

A preferred powder is a diamond powder having particles treated to have reduced number of edges, points, ridges and the like. The powder is close in appearance or in function to the arrangement depicted in FIG. 4. That is, it will be multimodal with most particles not having any edges or points with some being spherical and others like particles 54 and 62 having rounded edges. It may not be spherical and may have at least one major axis 63 and at least one minor axis 65. The diamond powder particles 50 have an aspect ratio from 1.0 to about 1.4. With typical multi-modal particle size distributions and with sizes under about 125 microns in effective diameter, it is believed that suspensions up to 95% by volume of solids can be formed as a slurry and which can be placed in a form for curing to a solid.

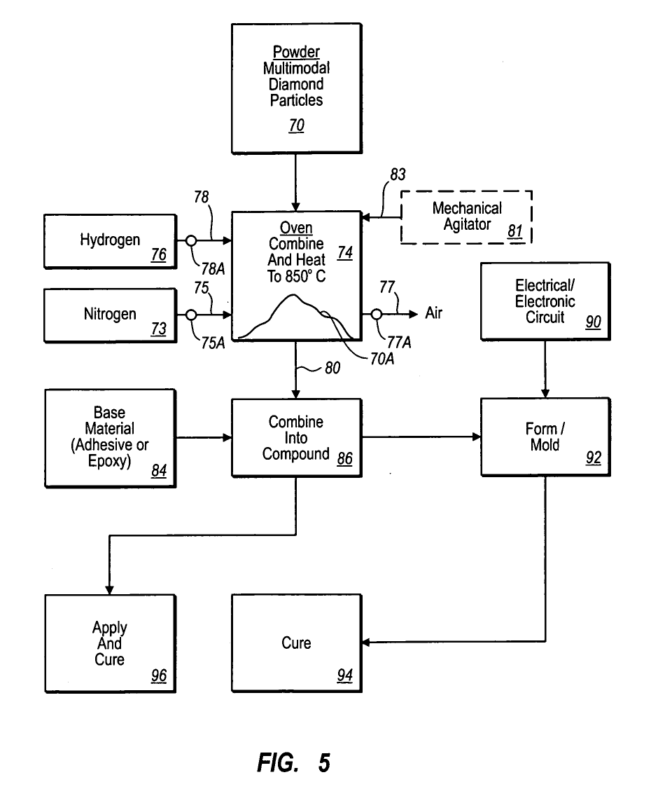

In preferred configurations, the powder will be hydrogenated as depicted in the process diagram of FIG. 5. In FIG. 5, multimodal powder is provided. It may be any suitable powder that has a suitable thermal coefficient and mechanical characteristics that allow it to be densely packed and mixed into a suitable base. Preferably diamond powder 70 with an aspect ratio from 1.0 to about 1.4 is provided with a maximum particle size of about 15 μm to about 50 μm.

A furnace 74 is provided that is typically electrically heated by resistance. While any number of suitable furnaces may be suitable, the furnace preferred so far is a long cylinder. Before heating the furnace, a supply of nitrogen 73 (or any other suitable inert gas like argon) is obtained and supplied to the furnace via a supply line 75. As the nitrogen 73 flows into the furnace, the air in the furnace 74 is urged out of the furnace 74 to the atmosphere via vent line 77.

A source of hydrogen 76 is provided; and hydrogen is supplied to the furnace 74 via a supply line 78. It is supplied to the furnace 74 after the nitrogen purge. That is, the vent 77 is operated to displace the nitrogen as the hydrogen enters. The hydrogen is retained in the furnace 74 which is operated to elevate the temperature to between about 400 degrees centigrade and 1250 degrees centigrade and preferably at about 850 degrees centigrade. The source 76 is preferably any suitable regulated supply. Stop valves 78A, 75A and 77A can be operated in appropriate sequences to vent the furnace 74 and to allow the nitrogen into it and then to allow the nitrogen to be forced out by the incoming hydrogen.

The furnace 74 is operated to heat the hydrogen with the powder 70 to a temperature of about 850 degrees centigrade. Hydrogenation can be effected between about 400 degrees Centigrade and 1250 degrees centigrade. A hydrogen plasma may also be used to hydrogenate the surface of the diamonds.

Other inert gases may also be used to in effect de-oxygenate the surface to the diamond and substitute molecules that enhance the transfer of heat. While the time necessary to hydrogenate will vary with the concentration of the hydrogen and the nature of the powder, the amount of time to hydrogenate diamond powder will vary from about 15 minutes to several hours with about 1 hour being preferred.

If a relatively large volume of powder 70 is supplied to the interior of the furnace 74, it is believed that mechanical agitation of the furnace 74 will enhance hydrogenation. That is, without agitation, the hydrogen may not reach the particles of powder 70 at the bottom of the large volume or pile 70A or at the contact points between the particles. A mechanical agitator 81 of any suitable type is optional and may be connected to the furnace 74 by an arm or member 83. When operated, the mechanical agitator 81 causes the furnace 74 to move rapidly or to rotate, or in a vessel with the powder in the furnace, in a manner that allows for the particles at the bottom of the pile 70A to be exposed to the hydrogen. It is believed that the hydrogen atoms replace the oxygen atoms bonded to the surface of the diamond. The result is hydrogenated powder 80 with better thermal heat transfer characteristics over powder that is not hydrogenated.

The hydrogenated powder 80 leaves the furnace 74 either in a tray or by any other suitable means. It is then placed in a suitable container 82 and mixed with a suitable base 84. For example, one may use anything ranging from a stir stick to an impeller/propeller driven by a motor to intermix and form the compound or material.

In some applications, an electronic circuit 90 is positioned in a mold. The compound 86 formed by mixing the hydrogenated powder 80 and more particularly the hydrogenated diamond powder, and even more specifically with a multimodal diamond powder with particles having aspect ratios from 1.0 to about 1.4 with a base, like an epoxy. When mixed, the compound is then placed into a mold 92 and then allowed to cure 94 to form a casing or housing in a desired shape. The casing or housing is thus electrically insulating with a high thermal conductivity and reduced coefficient of thermal expansion.

As further seen in FIG. 5, the powder, and preferably the hydrogenated multimodal diamond powder with particles having aspect ratios from about 1.4 to 1.0 is combined with a base which is a suitable adhesive in uncured form. Bismaleimide has been found to be quite suitable as an adhesive. The mixture 86 is then applied 96 to provide an adhesive having a high thermal conductivity and yet electrically insulating and a reduced coefficient of thermal expansion.

Alternately and preferably, the hydrogenated multimodal diamond powder 80 having particles with aspect ratios from 1.0 to about 1.4 is combined with a base which is a suitable material for potting the circuit inside the housing or casing of chip or electrical component. The mixture is then positioned inside of the chip or the like to provide a potting material having a high thermal conductivity that is yet electrically insulating and has a reduced coefficient of thermal expansion.

While heat transmission from electrical and electronic components is the context hereinbefore, it should be understood that housings and casings for many products have been selected to facilitate heat transfer. Metals used for gears, transmissions, motor housings and the like but a few of this class of products. Housings and casings having the thermal heat transfer characteristics as herein disclosed may be suitable for such products.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method for facilitating the transmission of heat from heat generating products, said method comprising:
providing a curable material;
selecting a powder-like material having a selected thermal conductivity greater than the thermal conductivity of said curable material and formed of multimodal particles having aspect ratios from 1 to about 1.6;
forming a compound by mixing said powder-like material with said curable material; and
positioning said compound proximate a heat generating product to facilitate the transfer of heat therefrom.

2. The method of claim 1 wherein said powder-like material is diamond powder.

3. The method of claim 2 wherein said curable material is an adhesive for securing said heat generating products to a substrate.

4. The method of claim 2 wherein said curable material is an adhesive for securing said heat generating product to a heat sink.

5. The method of claim 2 further including:
providing of a mold for forming the casing of an electronic product;
positioning said material in said mold; and
curing said material to form a casing for said electronic product.

6. The method of claim 5 wherein said curable material is an epoxy.

7. The method of claim 1 further including:
providing an oven;
first positioning said powder-like material in said oven;
supplying said furnace with hydrogen sufficient to hydrogenate said powder-like material;
heating said furnace with said hydrogen and said powder-like material therein to a temperature sufficient to form hydrogenated powder-like material; and
mixing said hydrogenated-powder-like material into said curable material.

8. The method of claim 7 wherein said powder-like material is multimodal diamond particles.

9. The method of claim 8 wherein said multimodal diamond particles have an aspect ratio from 1 to about 1.4.

10. The method of claim 9 wherein said curable material is epoxy.

11. The method of claim 9 wherein said curable material is an adhesive.

12. The method of claim 11 wherein said adhesive is from the group of adhesives that include bismaleimide.

13. The method of claim 11 wherein said adhesive is bismaleimide.

14. The method of claim 7 wherein the act of supplying said furnace with hydrogen comprises: providing a source of inert gas, connecting said source of inert gas to said oven, providing said furnace with a vent, operating said source of inert gas and said vent to vent all gas inside said furnace and to fill said furnace with inert gas, operating said source of hydrogen and said vent to fill said furnace with said hydrogen and vent said inert gas to the atmosphere.

15. The method of claim 1 wherein at least about 50% and less than about 90% of the volume of said compound is said powder-like material.

16. The method of claim 1 wherein at least about 75% and less than about 90% of the volume of said compound is said powder-like material.

17. The product of the method of claim 1.

18. A method for forming a compound for use with electronic components, said method comprising:
providing a curable material which is an electrical insulator when cured;
providing a powder-like material having a selected thermal conductivity greater than the thermal conductivity of said curable material and formed of multimodal particles having aspect ratios from at least 1 to about 1.4;
mixing said powder-like material with said curable material;
placing said curable material in a suitable mold for forming the casing or housing of an electronic component; and
curing said curable material.

19. The method of claim 18 wherein said curable material is an epoxy, wherein said powder-like material is diamond powder.

20. The method of claim 19 wherein said powder-like material is at least about 50 per cent by volume and less than about 90 percent by volume of said compound.

21. A compound for use to facilitate the transmission of heat from heat generating products, said compound comprising:
a curable material; and
a powder-like material mixed into said curable material, said curable material having a selected thermal conductivity greater than the thermal conductivity of said curable material and formed of multimodal particles having aspect ratios from at least 1 to about 1.4.

22. The compound of claim 21 wherein said curable compound is epoxy and said powder-like material is diamond powder.

23. The compound of claim 21 wherein said curable compound is bismaleimide.

24. A method for facilitating the transmission of heat from heat generating products, said method comprising:
providing a curable material;
selecting a powder-like material having a selected thermal conductivity greater than the thermal conductivity of said curable material and formed of multimodal particles having aspect ratios from at least 1 to about 1.4;
forming a compound by mixing said powder-like material with said curable material; and
positioning said compound proximate a heat generating product to facilitate the transfer of heat therefrom.

25. The method of claim 24 further including providing a heat sink and positioning said compound between said heat sink and said heat-generating product.

26. A method for forming a compound for use to facilitate the transmission of heat there through, said method comprising:
providing a curable material;
selecting a powder-like material having a selected thermal conductivity greater than the thermal conductivity of said curable material;
providing an oven;
positioning said powder-like material in said oven;
providing a source of hydrogen and connecting said source of hydrogen to said oven;
supplying said furnace with hydrogen sufficient to hydrogenate said powder-like material;
heating said furnace with said hydrogen and said powder-like material therein to a temperature sufficient to form hydrogenated powder-like material;
forming a compound by mixing said hydrogenated powder-like material with said curable material; and
curing said material with said hydrogenated powder-like material therein.

27. The method of claim 26 wherein said powder-like material is diamond powder.

28. The method of claim 27 wherein said curable material is an adhesive for securing said heat generating products to a substrate.

29. The method of claim 26 wherein said hydrogenated powder-like material has an aspect ratio from 1 to about 1.4.

30. A method for forming a compound for use to facilitate the transmission of heat there through, said method comprising:
providing a curable material;
selecting a powder-like material having a selected thermal conductivity greater than the thermal conductivity of said curable material, powder-like material being multimodal in form;
forming a compound by mixing said powder-like material with said curable material; and
curing said material with said powder-like material therein.

31. The method of claim 30 further including:
providing an oven;
first positioning said powder-like material in said oven;
providing a source of hydrogen and connecting said source of hydrogen to said oven;
supplying said furnace with hydrogen sufficient to hydrogenate said powder-like material; and
heating said furnace with said hydrogen and said powder-like material therein to a temperature sufficient to form hydrogenated powder-like material.
